(19) United States
(12) Patent Application Publication
(10) Pub. No.: US 2020/0058875 A1
(43) Pub. Date: Feb. 20, 2020

(54) LIGHT EMITTING MANUFACTURING METHOD

(71) Applicant: INT TECH CO., LTD., HSINCHU COUNTY (TW)

(72) Inventors: FENG YU HUANG, MIAOLI COUNTY (TW); HUEI-SIOU CHEN, TAIPEI CITY (TW); CHENG-HSIN CHEN, HSINCHU COUNTY (TW)

(21) Appl. No.: 16/232,880

(22) Filed: Dec. 26, 2018

Related U.S. Application Data
(60) Provisional application No. 62/719,039, filed on Aug. 16, 2018.

(51) Int. Cl. H01L 51/00; H01L 51/56; H01L 51/50; H01L 27/32

(52) U.S. Cl. CPC H01L 51/0018; H01L 51/56; H01L 2227/323; H01L 27/3246; H01L 51/5012

(57) ABSTRACT

The present disclosure provides a method for manufacturing a light emitting device. The method includes providing a substrate, and forming a photosensitive layer over the substrate. The method also includes patterning the photosensitive layer to form a first recess and a first bump. The method also includes disposing a first organic layer in the first recess. The method also includes patterning the photosensitive layer to form a second recess and a second bump. The method also includes disposing a second organic layer in the second recess.

### PRIORITY CLAIM AND CROSS-REFERENCE

This application claims the benefit of prior-filed provisional application No. 62/719,039, filed Aug. 16, 2018.

### TECHNICAL FIELD

The present disclosure is related to a manufacturing method of light emitting devices.

### BACKGROUND

Organic light emitting display (OLED) has been used widely in most high end electron devices. However, due to the constraint of current technology, the pixel definition is realized by coating a light emitting material on a substrate through a mask, and often, the critical dimension on the mask cannot be smaller than 100 microns. Therefore, pixel density having 800 ppi or higher becomes a difficult task for an OLED maker.

### SUMMARY

In the present disclosure, the light emitting units are formed by a photo sensitive material. The pixel definition is realized by a photolithography process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a light emitting device, in accordance with some embodiments of the present disclosure.

FIG. 2 is top view of a portion of a light emitting device, in accordance with some embodiments of the present disclosure.

FIGS. 3 to 14 illustrate a method of manufacturing a light emitting device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a light emitting device, especially, organic light emitting device (OLED), and a method of manufacturing thereof. In the present disclosure, an organic light emitting layer in the OLED is formed by photo lithography. In some embodiments, the organic light emitting layer is a polymer light emitting layer. In some embodiments, the organic light emitting layer includes several light emitting pixels or units.

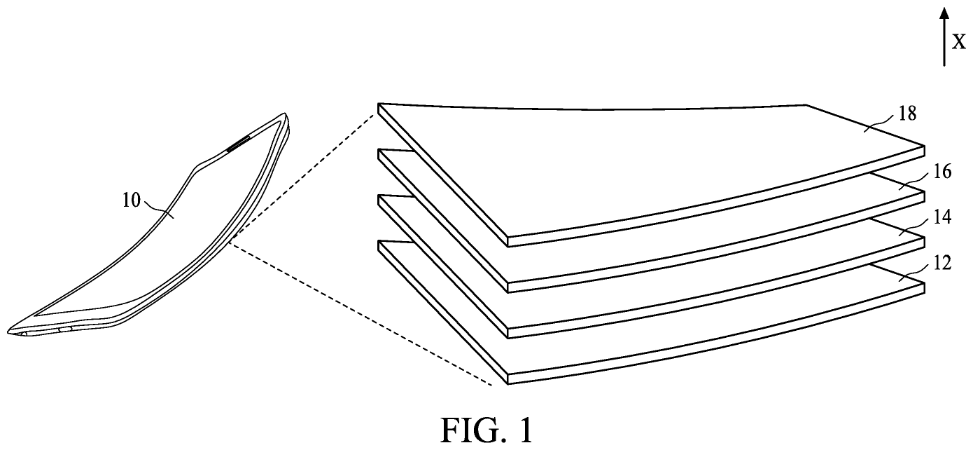

Referring to FIG. 1, FIG. 1 is a light emitting device 10, in accordance with some embodiments of the present disclosure. The light emitting device 10 can be a rigid or a flexible display. In some embodiments, the light emitting device 10 may have at least four different layers substantially stacked along a thickness direction X. In some embodiments, the at least four different layers includes layers 12 to 18, as shown in FIG. 1. In some embodiments, layer 12 is a substrate configured as a platform to have a light emitting layer 14 disposed thereon. Layer 16 is a cap layer to be disposed on the light emitting layer 14 and layer 18 is configured as a window for light emitting in/out the electronic device 10. In some embodiments, layer 16 is an encapsulation layer. In some embodiments, layer 18 can also be configured as a touch interface for the user, therefore the surface hardness of the might be high enough to meet the design requirement. In some embodiments, layer 16 and layer 18 are integrated into one layer.

In some embodiments, layer 12 might be formed with a polymer matrix material. In some embodiments, layer 12 has a bend radius being not greater than about 3 mm. In some embodiments, layer 12 has a minimum bend radius being not greater than 10 mm. The minimum bend radius is measured to the inside curvature, is the minimum radius one can bend layer 12 without kinking it, damaging it, or shortening its life. In some embodiments, several conductive traces may be disposed in layer 12 and form circuitry to provide current to the light emitting layer 14. In some embodiments, layer 12 includes graphene.

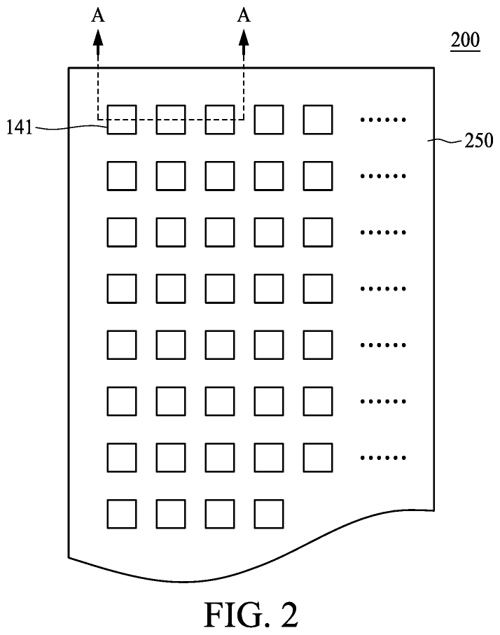

Referring to FIG. 2, FIG. 2 is top view of a portion of a light emitting device, in accordance with some embodiments of the present disclosure.

In some embodiments, a light emitting layer 200 may include many light emitting units 141. In some embodiments, the light emitting units may also be referred as light emitting pixels. In some embodiments, the light emitting layer 200 has a substrate 250. In some embodiments, the substrate 250 is configured to be able to provide current to the light emitting units 141. In some embodiments, the light emitting units 141 are configured as mesa disposed on the substrate 250. In some embodiments, the light emitting units 141 are configured to be in recesses of the substrate 250. In some embodiments, the light emitting units 141 can be arranged in an array. Each independent light emitting unit is separated from other adjacent light emitting units. In some embodiments, the separation distance between two adjacent light emitting units is between about 2 nm and about 100 um. In some embodiments, the separation distance is controlled to be at least not greater than about 50 um so that the density of the light emitting units 141 can be designed to be at least more than 700 ppi or 1200 ppi.

In some embodiments, a light emitting unit 141 has a width being between about 2 nm and about 500 um. In some embodiments the width is not greater than about 2 um.

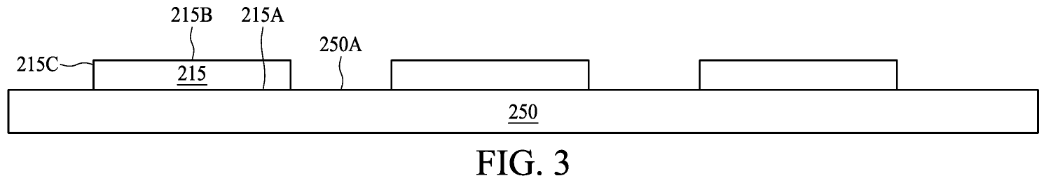

Referring to FIGS. 3 to 14, FIGS. 3 to 14 illustrate a method of manufacturing a light emitting device, in accordance with some embodiments of the present disclosure. Cross sectional views along ling AA in FIG. 2 are illustrated in FIGS. 3 to 14.

In FIG. 3, a substrate 250 is provided. The substrate 250 may include a TFT (thin film transistor) array. Several first electrodes 215 are disposed over a top surface 250A of the substrate 250. In some embodiments, each first electrode 215 includes a bottom surface 215A, a top surface 215B opposite to the bottom surface, and a sidewall 215C between the bottom surface 215A and the top surface 215B. In some embodiments, each first electrode 215 is configured to be connected to a circuit embedded in the substrate 250 at one side and to be in contact with a light emitting material at the other side. In some embodiments, the pattern of the first electrode array is designed for the pixel arrangement. In some embodiments, the top surface 250A of the substrate 250 is partially exposed through the first electrodes 215.

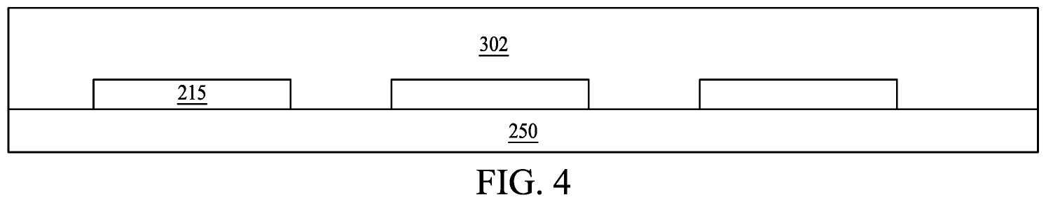

In FIG. 4, a photosensitive layer 302 is disposed over and covers the first electrodes 215. In some embodiments, the photosensitive layer 302 covers the top surface 215B and the sidewall 215C of the first electrodes 215. In some embodiments, the photosensitive layer 302 covers the exposed top surface 250A of the substrate 250. In some embodiments, the photosensitive layer 302 fills into the gaps between adjacent first electrodes 215.

In some embodiments, the photosensitive layer 302 is disposed by spin coating, or jetting. In some embodiments, the photosensitive layer 302 is spin-coated over the buffer layer 301.

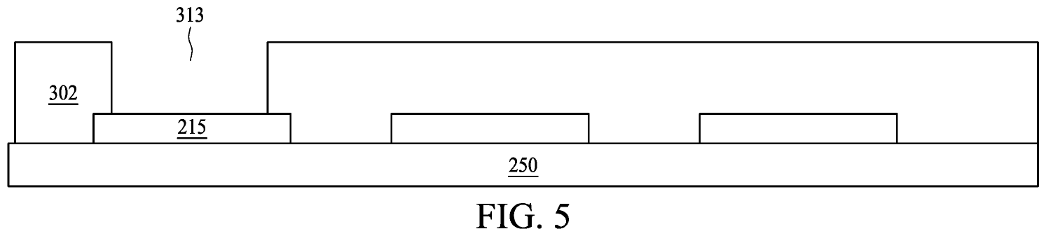

In FIG. 5, the photosensitive layer 302 is further patterned by a lithography process to expose a portion of the top surface 215B of one of the first electrodes 215 through a recess 313. In some embodiments, the removal operation in FIG. 5 is performed by wet etch.

In some embodiments, the recess 313 is formed while leaving the sidewalls 215C of the first electrodes 215 covered by the photosensitive layer 302. In other words, a portion of the top surface 215B of the first electrodes 215 is exposed, but the sidewalls 215C of the first electrodes 215 are remained covered. In some embodiments, a part of the photosensitive layer 302 forms a bump that covers a sidewall 215C of one of the first electrodes 215.

In some embodiments, the photosensitive layer 302 may include positive photoresist or negative photoresist. In some embodiments, the photosensitive layer 302 may include organic materials and inorganic materials. In some embodiments, organic materials may include, for examples, phenol-formaldehyde resins, epoxy resins, Ethers, Amines, Rubbers, acrylic acids, acrylic resins, acrylic epoxy resins, acrylic melamine. In some embodiments, inorganic materials may include, for examples, metal oxides and silicide.

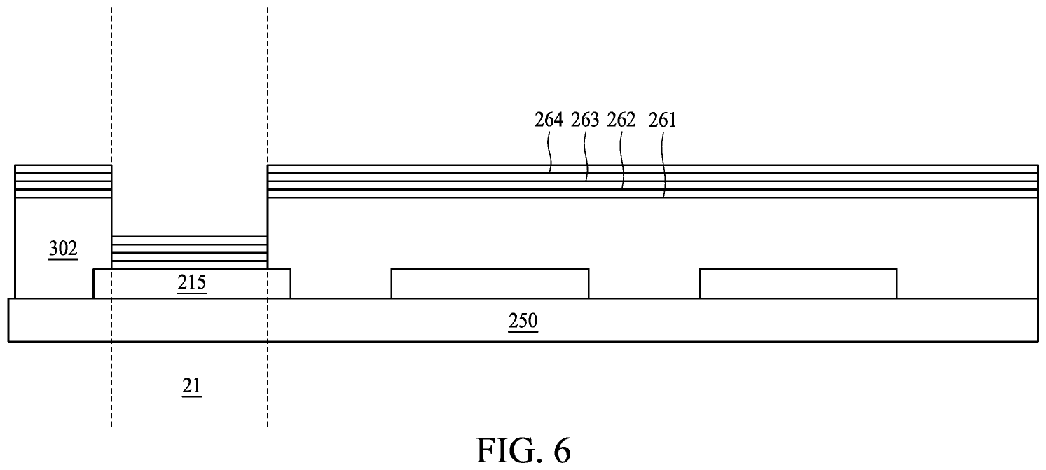

In FIG. 6, a first type carrier injection layer 261, a first type carrier transportation layer 262, an organic emissive layer (EM) layer 263, and a second type carrier transportation layer 264 are sequentially disposed over the exposed top surface 215B of first electrode 215 of a light emitting unit 21.

The photosensitive layer 302 covers up the other first electrodes 215 except the first electrode 215 of the light emitting unit 21. In some embodiments, the first type carrier injection layer 261, the first type carrier transportation layer 262, the organic EM layer 263, and the second type carrier transportation layer 264 are sequentially disposed over the photosensitive layer 302. In some embodiments, the layers 261-264 are disposed in the recess 313.

In some embodiments, the first type carrier injection layer 261 is an electron injection layer (EIL) and the first type carrier transportation layer 262 is an electron transportation layer (ETL). In some embodiments, the first type carrier injection layer 261 is a hole injection layer (HIL) and the first type carrier transportation layer 262 is a hole transportation layer (HTL). In some embodiments, the second type carrier transportation layer 264 can be a hole or electron transportation layer 264. In some embodiments, the second type carrier transportation layer 264 and the first type carrier transportation layer 262 is respectively configured for opposite types of charges. In some embodiments, a second type carrier injection layer (not shown in the figures) is further disposed over the second type carrier transportation layer 264. In some embodiments, the EM layer 263 is configured to emit a first color.

In some embodiments, the first type carrier injection layer 261, the first type carrier transportation layer 262, the organic EM layer 263, and the second type carrier transportation layer 264 may be formed by various deposition techniques such as Atomic Layer Deposition (ALD), Chemical Vapor Deposition (CVD), Physical Vapor Deposition (PVD), sputtering, plating, Laser Induced Thermal Imaging (LITI), inkjet printing, shadow mask, or wet coating.

In some embodiments, the first type carrier injection layer 261, the first type carrier transportation layer 262, the EM layer 263, and the second type carrier transportation layer 264 are configured to be divided into segments. In other words, the first type carrier injection layer 261, the first type carrier transportation layer 262, the EM layer 263, and the second type carrier transportation layer 264 are not continuously lining along the exposed top surface 250A and the first electrodes 215.

The light emitting unit 21 has a discontinuous and segmented first type carrier injection layer 261 disposed on the first electrode 215. The light emitting unit 21 has a discontinuous and segmented first type carrier transportation layer 262 disposed on the first type carrier injection layer 261. The light emitting unit 21 has a discontinuous and segmented EM layer 263 disposed on the first type carrier transportation layer 262. The light emitting unit 21 has a discontinuous and segmented second type carrier transportation layer 264 disposed on the EM layer 263.

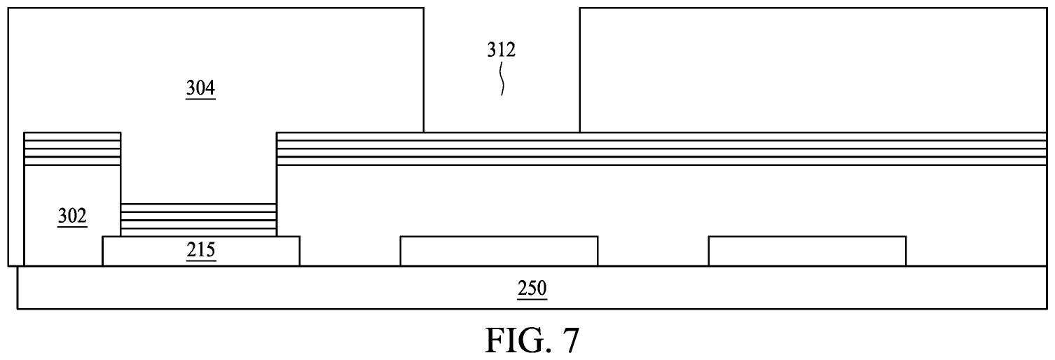

In FIG. 7, after the first type carrier injection layer 261, the first type carrier transportation layer 262, the EM layer 263, and the second type carrier transportation layer 264 of the first light emitting unit 21 is formed as illustrated in FIG. 6; a mask 304 is disposed on the second type carrier transportation layer 264. In some embodiments, the mask 304 is disposed on the topmost layer on the substrate 250.

In FIG. 7, the mask 304 is further patterned by a lithography process to expose a portion of the topmost layer, such as the second type carrier transportation layer 264, through a recess 312. In some embodiments, the removal operation in FIG. 7 is performed by wet etch. In some embodiments, the mask 304 may include one layer of a material. In some embodiments, the mask 304 may include several layers of different materials, such as one organic material layer stacking on one inorganic material layer. In some embodiments, the mask 304 may include a photosensitive material.

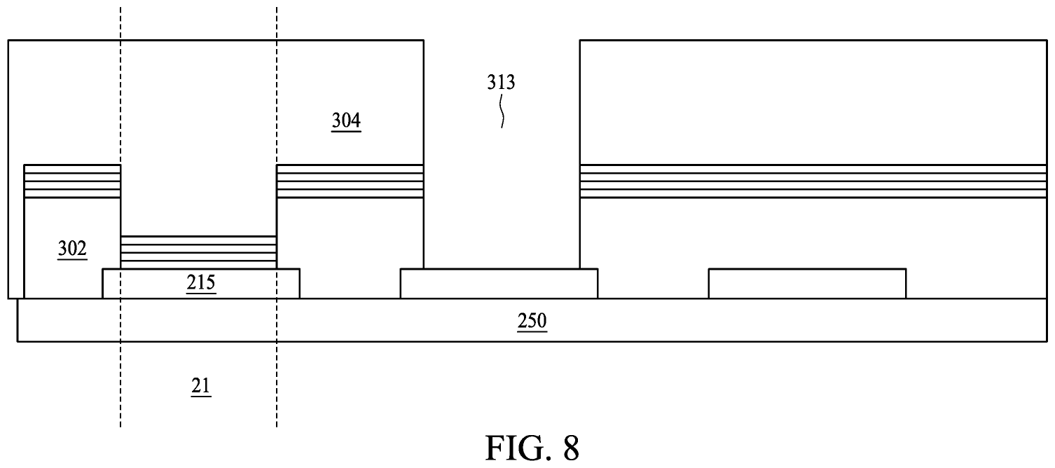

In FIG. 8, the photosensitive layer 302 is further patterned to expose another one of the first electrodes 215. In some embodiments, the photosensitive layer 302 is carved out substantially following the dimension of opening width of the recess 312 as shown in FIG. 7. Therefore, a portion of the top surface 215B of one of the first electrodes 215 is exposed through the recess 313.

In some embodiments, a width of the recess 312 may be bigger than a width of the recess 313, forming an undercut. In some embodiments, an undercut is formed to expand the recess 313 in order to expose more top surface 215B of one of the first electrodes 215.

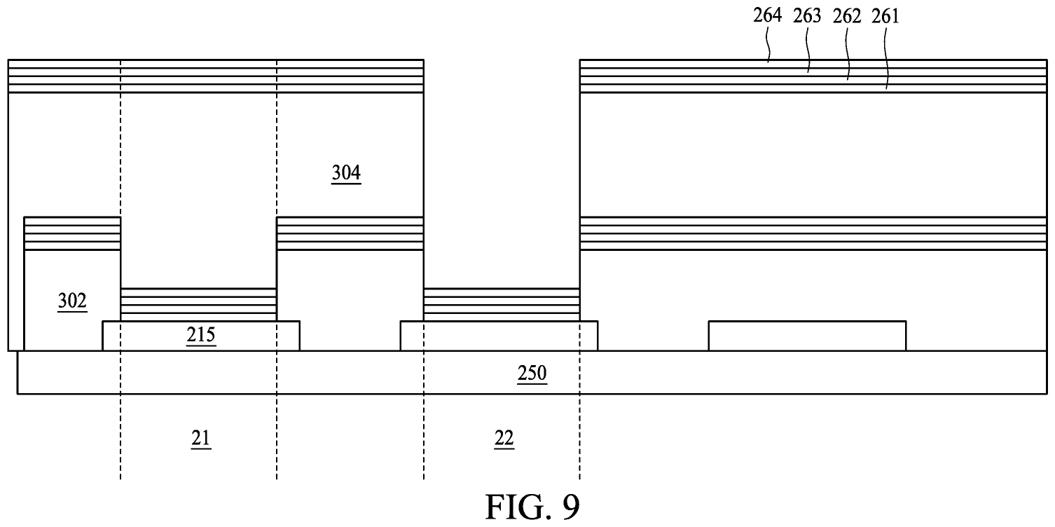

In FIG. 9, similar operations like FIG. 6 can be repeated to form a different colored light emitting unit. FIG. 9 illustrates the first type carrier injection layer 261, the first type carrier transportation layer 262, the organic EM layer 263, and the second type carrier transportation layer 264 are sequentially disposed over the exposed first electrode 215 of the second light emitting unit 22. The second light emitting unit 22 emits the second color, which is different from the first color of the first light emitting unit 21.

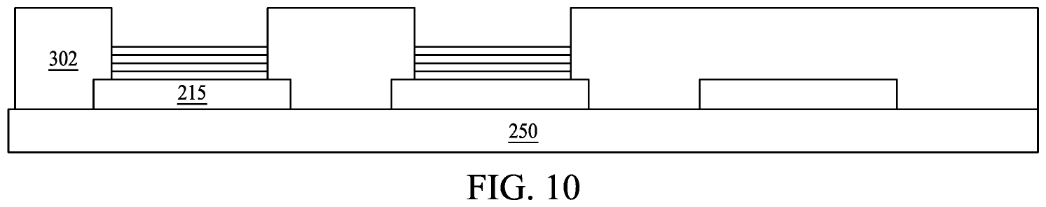

In FIG. 10, after the first type carrier injection layer 261, the first type carrier transportation layer 262, the organic EM layer 263, and the second type carrier transportation layer 264 of the second light emitting unit 22 are formed; the mask 304 is removed.

In some embodiments, the adhesive force between the photosensitive layer 302 and the substrate 250 is larger than the adhesive force between the photosensitive layer 302 and the mask 304. In some embodiments, the layers 261 to 264 above the photosensitive layer 302 are removed along with the mask 304. In some embodiments, the adhesive force between the photosensitive layer 302 and the substrate 250 is large enough that the layers 261 to 264 and the mask 304 may be removed without impacting the photosensitive layer 302.

In some embodiments, the remaining photosensitive layer 302 forms several bumps. In some embodiments, each bump fills the gap between two adjacent light emitting units. For examples, a bump fills the gap between the first light emitting unit 21 and the second light emitting unit 22. In some embodiments, the bumps are formed by leaving the patterned photosensitive layer 302 on the substrate 250 after every operations of disposing the organic layers. For examples, after the layers 261 to 264 of the first light emitting unit 21 is disposed as illustrated in FIG. 6, the patterned photosensitive layer 302 is leaving on the substrate 250 as illustrated in FIG. 6. A part of the patterned photosensitive layer 302 forms a bump. After the layers 261 to 264 of the second light emitting unit 22 is disposed as illustrated in FIG. 9, the patterned photosensitive layer 302 is leaving on the substrate 250 as illustrated in FIG. 10. A part of the patterned photosensitive layer 302 forms another bump.

The bumps are also called pixel defined layer (PDL). The bump can be formed in different types of shape. In some embodiments, the bump has a curved surface. In some embodiments, the shape of bump is trapezoid.

After the mask 304 is removed, similar operations like FIGS. 7 to 9 can be repeated to form a different colored light emitting unit.

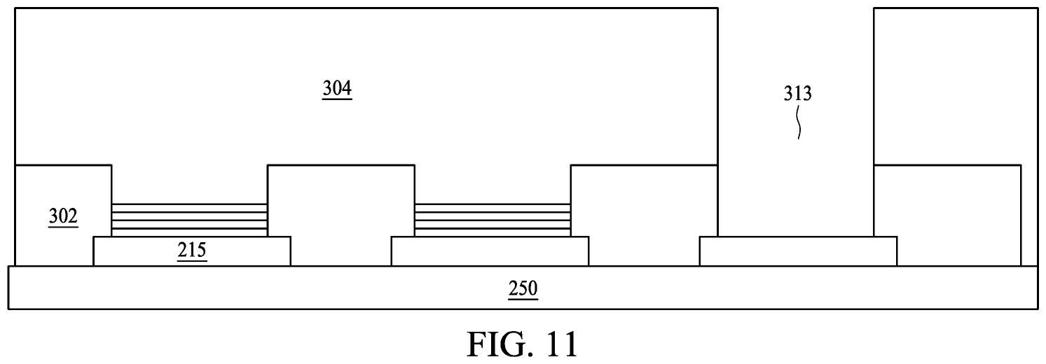

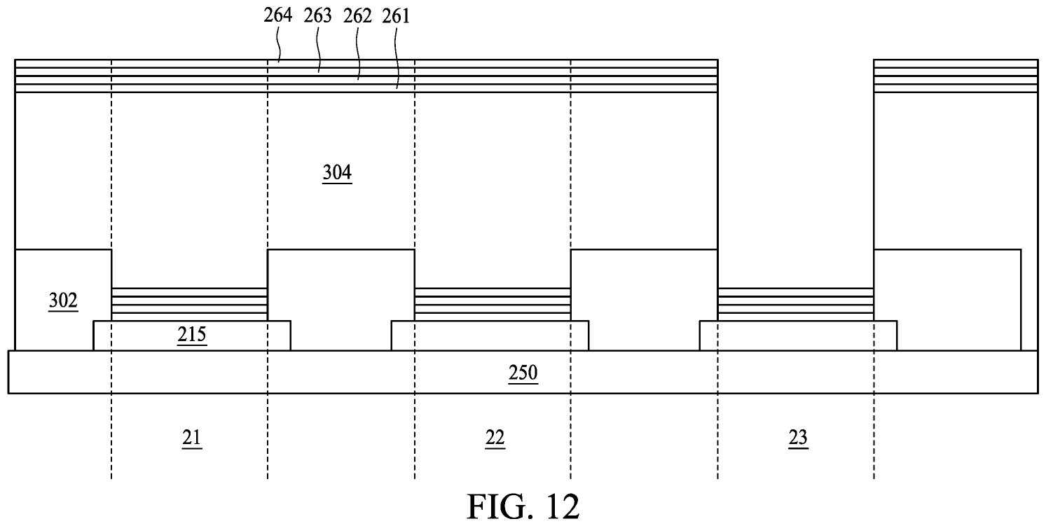

In FIG. 11, to form the third light emitting unit 23, another mask 304 is disposed to cover the first light emitting unit 21 and the second light emitting unit 22. FIG. 12 further illustrates the third light emitting unit 23 emitting the third color, which is different from the first color and the second color.

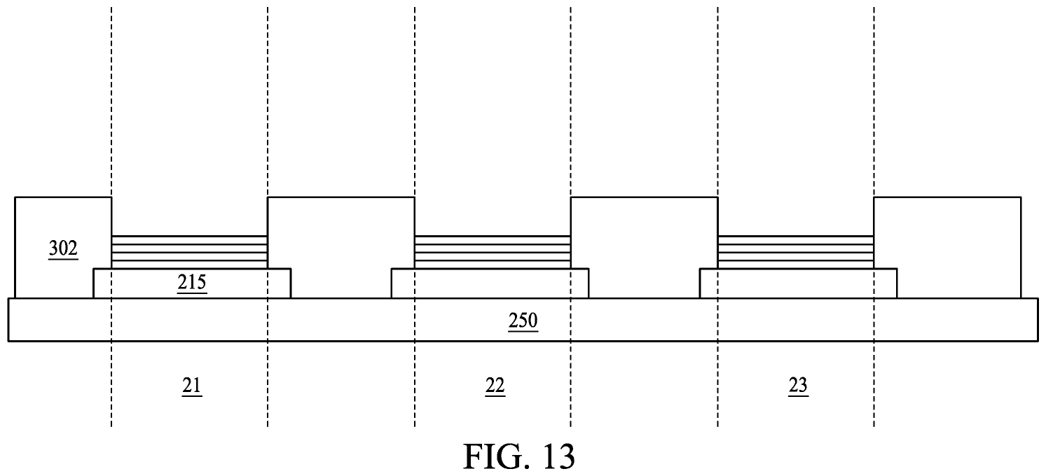

In FIG. 13, after the first type carrier injection layer 261, the first type carrier transportation layer 262, the EM layer 263, and the second type carrier transportation layer 264 of the third light emitting unit 23 is formed; the mask 304 is removed.

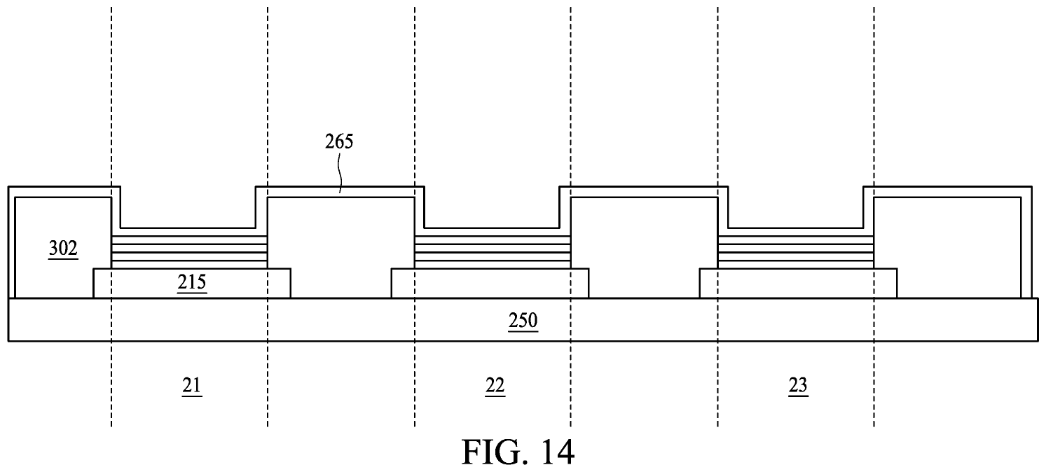

In FIG. 14, a second electrode 265 is disposed over the second type carrier transportation layers 264 of the light emitting units 21, 22, and 23. In some embodiments, the second electrode 265 may be disposed after the last second type carrier transportation layer 264 of one of the light emitting units is formed.

In some embodiments, the second electrode 265 can be metallic material such as Ag, Mg, etc. In some embodiments, the second electrode 265 includes ITO (indium tin oxide), or IZO (indium zinc oxide). In some embodiments, the second electrode 265 for the light emitting units is continuous.

In some embodiments, the first type carrier injection layer 261, the first type carrier transportation layer 262, the EM layer 263, the second type carrier transportation layer 264 are discontinuous and segmented among the light emitting units. In some embodiments, the second electrode 265 is commonly shared among the light emitting units.

Some embodiments of the present disclosure provide a method for manufacturing a light emitting device. The method includes providing a substrate, and forming a photosensitive layer over the substrate. The method also includes patterning the photosensitive layer to form a first recess and a first bump. The method also includes disposing a first organic layer in the first recess. The method also includes patterning the photosensitive layer to form a second recess and a second bump. The method also includes disposing a second organic layer in the second recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present invention. Accordingly, the appended claims are intended to include within their scope such processes, machines, manufacture, compositions of matter, means, methods, or steps.

What is claimed is:

1. A method for manufacturing a light emitting device, comprising:
providing a substrate;
forming a photosensitive layer over the substrate;
patterning the photosensitive layer to form a first recess and a first bump;
disposing a first organic layer in the first recess;
patterning the photosensitive layer to form a second recess and a second bump; and
disposing a second organic layer in the second recess.

2. The method for manufacturing a light emitting device in claim 1,
forming a first electrode on the substrate, wherein a top surface of the first electrode is exposed through the first recess.

3. The method for manufacturing a light emitting device in claim 2, wherein
the first electrode has a bottom surface opposite to the top surface, and a sidewall between the bottom surface and the top surface; and
wherein the photosensitive layer at least partially covers the top surface and a meeting point of the top surface and the sidewall.

4. The method for manufacturing a light emitting device in claim 2, further comprises:
disposing a second electrode on the first bump and the second bump.

5. The method for manufacturing a light emitting device in claim 1, further comprising:
disposing a mask on the first organic layer and the second organic layer; and
removing the mask without impacting the patterned photosensitive layer.

6. The method for manufacturing a light emitting device in claim 5, wherein an adhesive force between the patterned photosensitive layer and the substrate is larger than an adhesive force between the patterned photosensitive layer and the mask.
